(19) United States
(12) Patent Application Publication
(10) Pub. No.: US 2025/0278378 A1
(43) Pub. Date: Sep. 4, 2025

(54) CHIP INTERCONNECT WITH OPTICAL AND DIFFERENTIAL SIGNAL INTERFACES

(71) Applicant: QUALCOMM Incorporated, San Diego, CA (US)

(72) Inventor: Vladimir KEZIC, San Diego, CA (US)

(21) Appl. No.: 18/593,184

(22) Filed: Mar. 1, 2024

(51) Int. Cl. G06F 13/40; H01L 25/16; H03F 3/45

(52) U.S. Cl. CPC G06F 13/4068; H01L 25/167; G06F 2213/40; H03F 3/45475

(57) ABSTRACT

Aspects relate to a chip interconnect with optical and differential signal interfaces. An apparatus includes an optical fiber coupling port, a photodetector coupled to the optical fiber coupling port configured to generate an electrical signal in response to an optical signal received at the optical fiber coupling port, a converter coupled to receive the electrical signal and configured to generate a differential data signal based on the electrical signal, and a two-wire coupling port comprising output pins of the chip interconnect, the two-wire coupling port configured to couple the differential data signal to the output pins.

### TECHNICAL FIELD

Aspects of the present disclosure relate generally to chip interconnects and, in particular, to chip interconnects with optical and differential signal interfaces.

### BACKGROUND

In many applications, e.g., computing, virtual reality, automotive electronics, mobile devices, robotics, machine vision, etc., a processor, controller, or chipset is coupled to sensors that generate significant data. The sensor data is sent to the chipset at a high data rate, especially in applications where the data is being used to guide an actuator or guide a user. Similarly, the processor, controller, or chipset may be coupled to a display or other peripheral device to which significant data is sent.

In e.g., a mobile device, the chipset, or a System-on-Chip (SoC) is coupled to peripherals using multiple copper wires, leads or printed circuit board (PCB) traces. Parallel bus interfaces are conducted through the multiple wires for cameras, e.g., Camera Serial Interface (CSI) and for a display, e.g., Digital Video Interface (DVI). The interfaces carry data, control, and management signals. For cameras, an SoC may have a different parallel bus connector for each camera. Similarly, there may also be multiple parallel bus connectors for each of a multiple set of displays or display segments. The switching activity is affected by the number of switches that are active at the same time and by the switching frequency of the integrated circuit. Thermal mitigation often includes putting parts of an integrated circuit into idle or sleep states and reducing the frequency of the input clock that drives the switches. These thermal mitigation measures may also reduce the performance of the integrated circuit.

### BRIEF SUMMARY

The following presents a summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

In one example, a chip interconnect includes an optical fiber coupling port, a photodetector coupled to the optical fiber coupling port configured to generate an electrical signal in response to an optical signal received at the optical fiber coupling port, a converter coupled to receive the electrical signal and configured to generate a differential data signal based on the electrical signal, and a two-wire coupling port comprising output pins of the chip interconnect, the two-wire coupling port configured to couple the differential data signal to the output pin.

In one example, a chip interconnect includes a two-wire coupling port having two input pins configured to couple a differential data signal from a source chip to the chip interconnect, a laser coupled to the amplifier configured to convert the differential data signal to an optical signal, and an optical fiber coupling port configured to couple the optical signal to an external optical fiber coupled to the chip interconnect.

In one example, a computing system includes a processing chip configured to receive a differential data signal at a two-pin input port; and a chip interconnect comprising a two-wire coupling port configured to couple the differential data signal to the two-pin input port of the processing chip. The chip interconnect includes an optical fiber coupling port coupled to an optical fiber and configured to receive an optical signal from a data source through the optical fiber, a photodetector coupled to the optical fiber coupling port and configured to generate an electrical signal based on the optical signal at the optical fiber coupling port, and a converter coupled to receive the electrical signal and configured to generate the differential data signal based on the electrical signal and coupled to the two-wire coupling port to provide the differential data signal to the two-wire coupling port.

In one example, a method includes receiving an optical signal at an optical fiber coupling port, generating an electrical signal in response to the optical signal received at the optical fiber coupling port at a photodetector, receiving the electrical signal and generating a differential data signal based on the electrical signal at a converter, and coupling the differential data signal to a two-wire coupling port.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the described implementations are intended to include all such aspects and their equivalents.

### BRIEF DESCRIPTION OF THE DRAWINGS

FIG. 1 illustrates a block diagram of a computing system using chip interconnects, in accordance with aspects of the disclosure.

FIG. 2 illustrates a block diagram of a chip interconnect having a receive side coupled to an optical fiber and an SoC coupled to the chip interconnect, in accordance with aspects of the disclosure.

FIG. 3 illustrates a block diagram of a chip interconnect 304 having a transmit side coupled to an optical fiber, in accordance with aspects of the disclosure.

FIG. 4 is a process flow diagram of a process of operating interconnect chips with optical and differential signal interfaces, in accordance with aspects of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, these concepts may be practiced without these specific details. In some instances, well-known structures and components are shown in block diagram form in order to avoid obscuring such concepts.

Data rates on SoCs (chipsets) are increasing and for some applications the distance to various peripheral devices is increasing. In addition, the number of peripherals, including cameras and displays is also increasing. Electrical interfaces such as Camera Serial Interface (CSI), Display Serial Interface (DSI), and Digital Video Interface (DVI) may have 8, 9, or 10 pin connectors. Different electrical interfaces may have different physical interfaces and different protocols further increasing the complexity for a chip that hosts multiple different interfaces. Pins for these connectors have a cost in chip size, design, and manufacturing. Multiple connectors may use a significant part of the space available on the edges of an SoC. While the present description is in the context of 8, 9, or 10 pin connectors as with CSI, DSI, or DVI, any parallel or multiple pin signal may be applied as an input to the fiber optic interfaces, differential interfaces, and components described herein.

Copper connectors suffer from signal integrity issues, e.g., insertion loss due to the inherent active capacitance. In addition, signal interference may result from crosstalk with various radios surrounding the chipset. Copper cable thickness also increases with distance in order to maintain the performance, data rate, and signal quality. Multimode optical fiber, by contrast, has very little insertion loss and loses very little of its original signal strength over any relevant distance with and no change in the cable thickness for the optical fiber.

In order to reduce the number of input/output (I/O) connectors on a SoC and other chips compared to common 8, 9, or 10 pin connectors, a receive side chip interconnect can be configured to receive an optical signal from a data source chip, e.g., camera, memory, or processor, and convert the optical signal to a differential data signal at an input to a data sink chip, e.g., an SoC or other chip. The differential data signal can then be driven into the data sink chip and, inside the data sink chip, the differential data signal may be deserialized into a usable format ready for further digital signal processing. The receive side chip interconnects may be located a short distance from the data sink chip to reduce signal integrity issues.

On the transmit side, a symmetrical approach may be used. As an example, a data source chip, e.g., a sensor, data source, or SoC operating as a peripheral device, may be configured to drive a differential data signal, instead of an 8, 9, or 10 pin signal, on a pair of pins to a transmit side chip interconnect with an electrical-to-optical interface. Alternatively, the data source may drive the 8, 9, or 10 pin signal to the transmit side chip interconnect which converts it to a suitable differential or single pin signal. From the two-pin input, the transmit side chip interconnect can be configured to interface the data source chip to an optical fiber. The optical fiber is coupled to the receive side chip interconnect which, in turn is coupled to a differential data interface of the data sink chip. The transmit side chip interconnects may also be located a short distance from the data source chip to reduce signal integrity issues. A single chip interconnect may be configured to operate as a receive side chip interconnect and a transmit side chip interconnect to support receiving from an optical fiber and transmitting to an optical fiber. The chip interconnect may also be configured to support multiple optical fibers and multiple differential data signals.

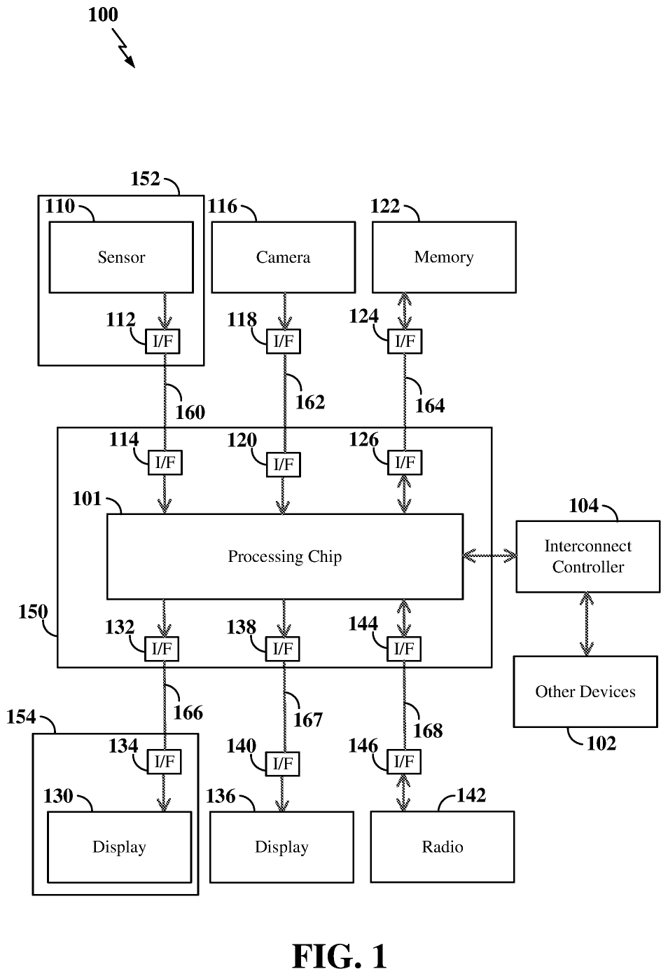

FIG. 1 is a block diagram of a computing system using chip interconnects according to some aspects. A processing chip 101, e.g. an SoC, CPU, GPU, or other chip, is coupled to any of a variety of other devices 102 through an interconnect controller 104. The other devices may include I/O, storage, processing, timing, maintenance and control, and any other types of devices. Any suitable bus and protocol or combination of busses and protocols may be used.

In addition, the computing system includes one or more sensors 110, e.g., optical, magnetic, inertial, touch or any other type of sensor. The sensor has a differential data output coupled to a chip interconnect 112. The chip interconnect 112 converts the differential data signal to an optical signal that is coupled through an optical fiber 160 to a second chip interconnect 114. The second chip interconnect 114 is coupled to the processing chip 101 to receive the optical signal from the optical fiber 160, convert it to a differential data signal and provide the differential data signal to the processing chip 101. In this example, the data is shown as flowing only from the sensor 110 to the processing chip 101. There may be no return path from the processing chip 101 to the sensor 110. The return path may be electrical for low data rates along a similar path through other devices 102 or through a similar optical coupling using the same or different chip interconnects.

The chip interconnects are shown as external to the sensor and to the processing chip. This allows the fabrication of the chip interconnects to be performed for such a purpose. In some examples, a silicon photonic chip is used. Si₃N₄ has been used for waveguides, allowing for a silicon bases for the chip interconnect. In some examples, gallium nitride, lithium niobate, germanium, or another fabrication technology may be used. The chip interconnects may also support a return path through a second optical fiber.

The computing system includes one or more cameras 116, e.g., visible, infrared, lidar or any other type of camera. The camera has a differential data output coupled to a chip interconnect 118. The chip interconnect 118 converts the differential data signal from the camera to an optical signal that is coupled through an optical fiber 162 to a second chip interconnect 120. The second chip interconnect 120 is coupled to the processing chip 101 to receive the optical signal from the optical fiber 162, convert it to a differential data signal and provide the differential data signal to the processing chip 101. The camera data may be still, motion, time lapse, multiple view, or any other camera data.

The computing system includes one or more memories 122, e.g., optical, magnetic, solid state, spinning disk or any other type of memory. The memory has a differential data output coupled to a chip interconnect 124. The chip interconnect 124 converts the differential data signal to an optical signal that is coupled through an optical fiber 164 to a second chip interconnect 126. The second chip interconnect 126 is coupled to the processing chip 101 to receive the optical signal from the optical fiber 164, convert it to a differential data signal and provide the differential data signal to the processing chip 101. In this example, the data is shown as flowing in both directions to and from the memory. The processing chip 101 may present a differential data signal to the chip interconnect 126 which couples the data to the optical fiber 164 or to a different optical fiber (not shown). The optical fiber 164 carries the data to the first chip interconnect 124 at which is it provided to the memory. Data and control may be carried on any of the optical fiber connections through the chip interconnect. In some examples, at least some of the control data is carried on a different medium independent of the optical fiber connections.

The sensor 110, camera 116, and memory 122 are each an external data source from the perspective of the nearest chip interconnect 112, 118, 124 which are transmit chip interconnects to transmit the differential data signal received from the respective data source to the processing chip 101 through a respective chip interconnect 114, 120, 126. The processing chip is an external processing chip from the perspective of the sensor 110, camera 116, and memory 122 and the chip interconnects 112, 114, 118, 120, 124, 126.

The computing system includes one or more displays 130, 136. The processing chip 101 has differential data outputs coupled to a respective first chip interconnect 132, 138. The chip interconnects 132, 138 convert the differential data signals to optical signals that are coupled through respective optical fibers 166, 167 to a respective second chip interconnect 134, 140. The second chip interconnects 134, 140 are coupled to the respective display 130, 136 to receive the optical signals from the optical fibers 166, 167, convert them to differential data signals and provide the differential data signals to the respective display 130, 136. In this example, the data is shown as flowing only from the processing chip 101 to the sensor 110.

The computing system includes one or more radios 142, e.g. Wi-Fi, Bluetooth, cellular, broadcast, etc. The processing chip 101 has a differential data output coupled to a first chip interconnect 144. The chip interconnect 144 converts the differential data signal to an optical signal that is coupled through an optical fiber 168 to a second chip interconnect 146. The second chip interconnect 146 is coupled to the radio 142 to receive the optical signal from the optical fiber, convert it to a differential data signal and provide the differential data signal to the radio 142. In this example, the data is shown as flowing in both directions which, as mentioned above, may be performed on the one optical fiber 168, on two optical fibers or through a different path.

In some examples, the chip interconnects are formed as independent packages. The processing chip 101 and the nearest chip interconnects 114, 120, 126, 132, 138, 144 may all be attached to a single substate 150, e.g., printed circuit board, interposer, etc. Other components (not shown) may also be mounted to the same substrate 150. In some examples, the substrate is a package substrate, and the chip interconnects are packaged together with one or more processing chips. Similarly, a sensor 110 or other peripheral may be attached to a peripheral substrate 152 together with the nearest chip interconnect 112. The two components may be packaged together on the substrate or be in separate packages. While one peripheral substrate 152 is shown, any one or more of the source peripherals may be mounted to a substrate with one or more other source peripherals and one or more chip interconnects. Similarly, a display 130 or other sink peripheral may be attached to a sink substrate 154 together with the nearest chip interconnect 134. While one sink substrate 154 is shown, any one or more of the sink peripherals may be mounted to a sink substrate 154 with one or more other sink peripherals and one or more chip interconnects. Using circuit boards or package substrates, the chip interconnects may be mounted to the respective substrate and the two-wire differential data signal may be coupled to the respective peripheral or SoC using circuit board traces, e.g. copper traces printed on the substrate.

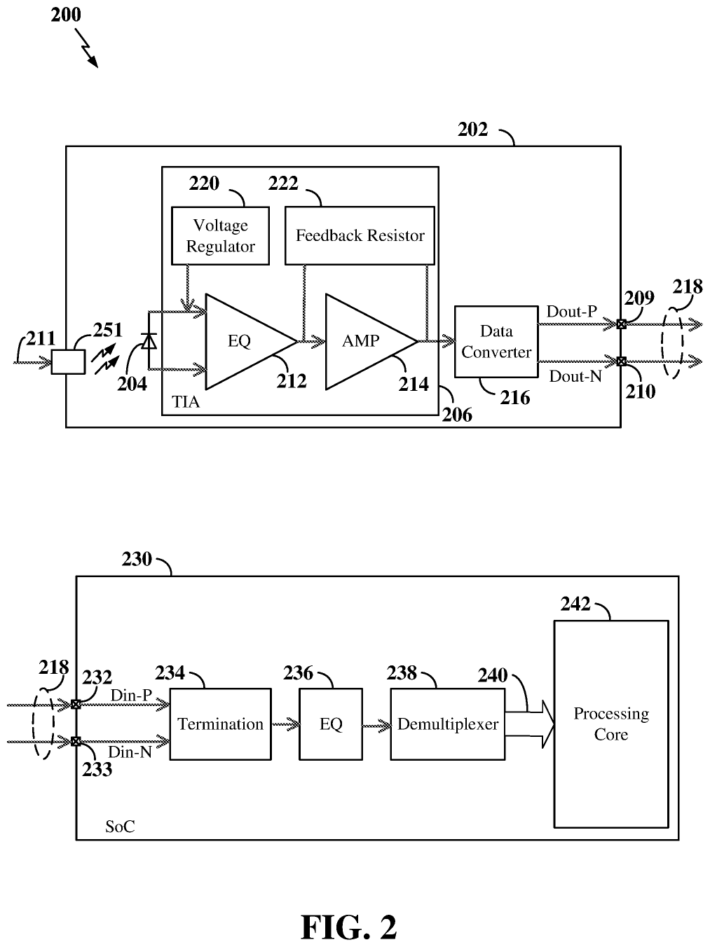

FIG. 2 is a block diagram of a chip interconnect 202 having a receive side coupled to an optical fiber 211 and an external processing chip, e.g., SoC 230, coupled to the chip interconnect. The optical fiber 211 carries an optical signal from an external data source and attaches to an optical fiber coupling port 251 using any suitable coupler, e.g. waveguide, tube, fiber, etc. The optical fiber coupling port conducts an optical signal from the optical fiber 211 to a photodetector 204, e.g. a photodiode. Germanium photodiodes may be used as the photodetector or any other suitable substance, e.g., a III-V material such as InP. The photodetector 204 generates a current signal based on the optical signal. The current signal is an electrical signal to be applied to a transimpedance amplifier (TIA) 206. The TIA 206 includes an equalizer 212 configured to precondition the electrical signal and an operational amplifier (op-amp) 214 configured to amplify the electrical signal and provide the amplified electrical signal to a data converter 216.

The TIA 206 acts as a front-end amplifier for the optical sensors such as the photodetector 204, converting the sensor's output current signal to a voltage signal. A voltage regulator 220 regulates the voltage from the photodetector 204 into the TIA 206. The TIA 206 may be understood as having a feedback resistor (FR) 222 across the op amp 214. The FR 222 feeds the op-amp 214 output back to its input. The FR 222 converts the current (I) to a voltage (V_{OUT}) using Ohm's law, V_{OUT}=I×FR. The value of the FR 222 may be adjusted by calibration, Direct Current (DC) offset or other controls. The FR 222 may also include other components including a controller to regulate the amplifier, e.g., by adjusting the calibration and DC offset.

The electrical signal from the op-amp 214 is provided to a data converter 216 that is coupled to receive the electrical signal from the op amp 214 and to generate a differential data signal 218 based on the electrical signal. The data converter 216 is coupled to a two-wire coupling port having two output pins, a Dout-P pin 209 and a Dout-N pin 210. The data converter 216 drives the differential data signal 208 onto the two-wire coupling port. The differential data signal 218 at the output pins, Dout-P pin 209 and Dout-N pin, 210, is a differential data signal 218 sent through a two-wire connection, e.g., wires or circuit board traces, to couple the differential data signal to input pins, D-in-P pin 232 and Din-N pin 233 of a two-wire coupling port of the SoC 230 or other processing chip.

The chip interconnect 202 may be formed on a single substrate, e.g. semiconductor substrate, such as a silicon substrate or germanium substrate, indicated by the outline of the chip interconnect 202 separate from the SoC. The photodetector 204, TIA 206, including the equalizer 212, op-amp 214, the voltage regulator 220, the FR 222, and the data converter 216 may all be formed on the substrate and packaged independent of the external processing chip, e.g. SoC 230. In some examples, multiple chip interconnects 202 may be formed on a single substrate to support multiple peripherals and two-way communication between the SoC 230 and the peripherals.

As shown, a fiber-optic medium, e.g., the optical fiber 211, is combined with a data converter 216, e.g., a data serializer/deserializer (SERDES), to improve signal integrity and reduce the number of chip pins on the SoC 230 and any other connected components. For electrical signals, the data converter 216 operates as a serializer to convert the electrical signal to a differential data signal. The serial 2-wire differential data signal 218 out of the chip interconnect 202 is coupled to a 2-pin interface as a coupling port on the SoC 230.

The SoC 230 then converts the 2-wire, serial, differential, data signal 218 to a packetized, parallel format for a parallel bus 240 that the SoC 230 uses to process the incoming data from the chip interconnect 202. The differential data signal 218 is coupled through the two-wire coupling port to an electrical termination 234. The terminated differential data signal is equalized by equalizer 236 and then applied to a demultiplexer 238, e.g., a SERDES. The demultiplexer 238 recovers the clock of the differential data signal, performs any other data correction or error recovery to the differential data signal and then demultiplexes the signal into a suitable parallel format for a parallel bus 240 for the SoC 230. For example, the parallel data signal from the demultiplexer 238 may be coupled to processing core 242. The nature of the processing core 242 may be adapted to suit the functions and peripherals of the SoC 230.

In some examples, the chip interconnect 202 is placed close to but separate from the SoC 230. In some examples, the chip interconnect 202 is formed as a separate package from a package of the SoC 230. The packages may be mounted to a common substrate, e.g., a printed circuit board, and the differential data signal 218 may be implemented as traces on the substrate, e.g., circuit board traces on a printed circuit board.

The chip interconnect 202 and SoC 230 may have many other components (not shown) for power, control, and administration. There may be more components to amplify, filter, or otherwise process the signals. The chip interconnect 202 and SoC 230 may further include additional coupling ports than that shown. In addition, to the receive side shown, there may also be one or more transmit sides coupled to a single peripheral or Soc 230.

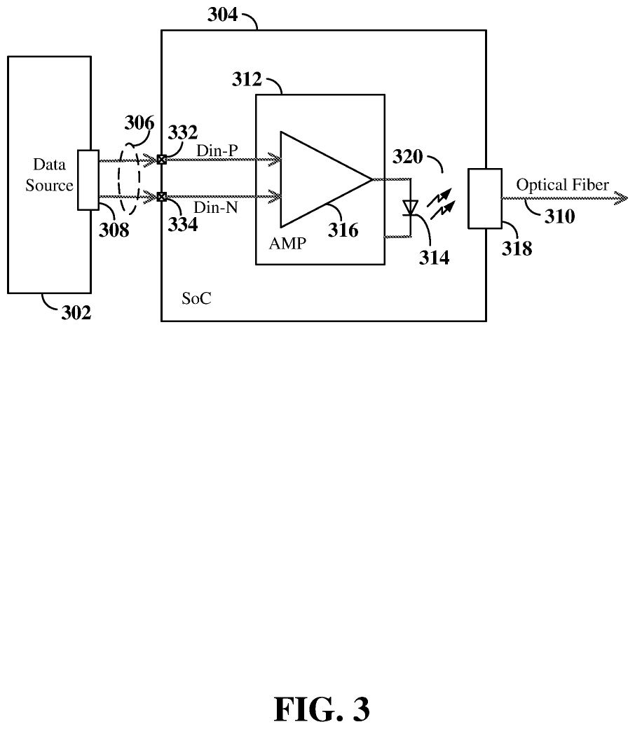

FIG. 3 is a block diagram of a chip interconnect 304 having a transmit side coupled to an optical fiber 310. A source chip 302 is an external data source and may be a peripheral, e.g., a sensor, camera, or memory, or a processing chip, e.g. an SoC. The source chip 302 generates data and converts the data from a format suited for the uses of the source chip 302 to a differential data signal 306 that is transmitted from a source chip output port 308 to a two-wire coupling port of a chip interconnect 304. The chip interconnect 304 two-wire coupling port has a Din-P pin 332 and a Din-N pin 334 to receive the differential data signal 306 and is coupled to an amplifier 312.

The amplifier 312 converts the differential data signal 306 to a current to drive a laser 314. Using a differential amp 316 coupled to the laser 314 to generate a current amplitude signal to drive the laser 314. The laser 314 converts the electrical signal, e.g., the current signal, to an optical signal 320, e.g., pulses of light. The optical signal 320 is coupled to an optical fiber 310 through an optical fiber coupling port 318. The optical fiber 310 is coupled to a waveguide or other suitable structure of the coupling port 318 and extends from the chip interconnect 304 to an external data sink (not shown), e.g. a sink peripheral or a processing chip, as appropriate to the implementation.

As shown, the multiple pin interconnects of 8, 10 or more pins that are used for peripherals, may be replaced with two-wire or two-pin input ports for differential data signals. This greatly reduces the number of pins to support each peripheral at high data rates. The optical fiber connections may extend through short or long distances up to several meters to support different implementations. The signal integrity is preserved through multiple electromagnetic interferers and across many temperatures by using optical fiber. In some examples, the chip interconnects are constructed as chiplets.

The chip interconnect 304 may have many other components (not shown) for power, control, and administration. There may be more components to amplify, filter, or otherwise process the signals. The chip interconnect 304 may also include many more coupling ports than that shown. In addition, to the transmit side shown, there may also be one or more receive sides coupled to a single peripheral.

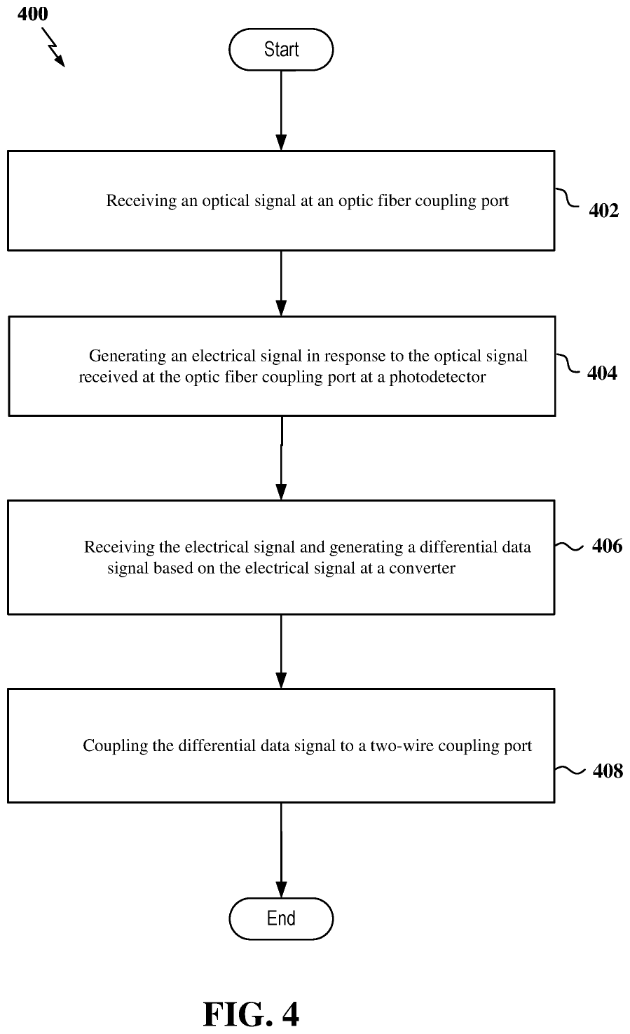

FIG. 4 is a process flow diagram of a process of operating interconnect chips with optical and differential signal interfaces according to some aspects. At block 402, the process includes receiving an optical signal at an optical fiber coupling port. The optical signal may be from any suitable data source or may contain commands or control data from a data sink.

The optical signal may be generated by a transmit side chip interconnect place in proximity to a data source or sink. In examples, the transmit side chip interconnect receives a differential data signal from a data source chip, or any other type of chip, amplifies the differential data signal and generates the optical signal. The optical signal is coupled to the optical fiber within which the optical signal may be carried from the data source chip across a short or long distance, including a distance with electrical interference.

At block 404, the process includes generating an electrical signal in response to the optical signal received at the optical fiber coupling port at a photodetector. At block 406, the process includes receiving the electrical signal and generating a differential data signal based on the electrical signal at a converter. The chip interconnect may include an amplifier, e.g., a transimpedance amplifier, coupled to the photodetector configured to amplify the electrical signal and provide the signal to a converter. The transimpedance amplifier may include an equalizer configured to precondition the electrical signal and an amplifier to convert the current signal of the photodetector to a voltage signal. The voltage signal may be coupled from the transimpedance amplifier to a serializer to convert the electrical signal to the differential data signal. The converter drives the differential data signal to the output pins to a two-wire coupling port.

At block 408, coupling of the differential data signal to a two-wire coupling port is performed. The output pins may be configured to be coupled to a two-pin input port for a differential data signal of an external processing chip.

As used herein, “or” is intended to be interpreted in the inclusive sense, unless otherwise explicitly indicated. For example, “a or b” may include a only, b only, or a combination of a and b. As used herein, a phrase referring to “at least one of” or “one or more of” a list of items refers to any combination of those items, including single members. For example, “at least one of: a, b, or c” is intended to cover the examples of: a only, b only, c only, a combination of a and b, a combination of a and c, a combination of b and c, and a combination of a and b and c.

The various illustrative components, logic, logical blocks, modules, circuits, operations, and algorithm processes described in connection with the implementations disclosed herein may be implemented as electronic hardware, firmware, software, or combinations of hardware, firmware, or software, including the structures disclosed in this specification and the structural equivalents thereof. The interchangeability of hardware, firmware and software has been described generally, in terms of functionality, and illustrated in the various illustrative components, blocks, modules, circuits and processes described above. Whether such functionality is implemented in hardware, firmware or software depends upon the particular application and design constraints imposed on the overall system.

The various illustrative logical blocks, modules, and circuits described in connection with the exemplary aspects disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor may be a microprocessor and the processor may be any conventional processor, controller, microcontroller, or state machine. A processor may also be implemented as a combination of computing devices, for example, a combination of a DSP and a microprocessor, a plurality of microprocessors, one or more microprocessors in conjunction with a DSP core, or any other such configuration.

Various modifications to the implementations described in this disclosure may be readily apparent to persons having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, various features that are described in this specification in the context of separate implementations also can be implemented in combination in a single implementation. Conversely, various features that are described in the context of a single implementation also can be implemented in multiple implementations separately or in any suitable subcombination. As such, although features may be described above as acting in particular combinations, and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flowchart or flow diagram. However, other operations that are not depicted can be incorporated in the example processes that are schematically illustrated. For example, one or more additional operations can be performed before, after, simultaneously, or between any of the illustrated operations. In some circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

The following provides an overview of examples of the present disclosure.

Example 1: A chip interconnect comprising: an optical fiber coupling port; a photodetector coupled to the optical fiber coupling port configured to generate an electrical signal in response to an optical signal received at the optical fiber coupling port; a converter coupled to receive the electrical signal and configured to generate a differential data signal based on the electrical signal; and a two-wire coupling port comprising output pins of the chip interconnect, the two-wire coupling port configured to couple the differential data signal to the output pins.

Example 2: The chip interconnect of example 1, further comprising an amplifier coupled to the photodetector configured to amplify the electrical signal and provide the electrical signal to the converter.

Example 3: The chip interconnect of example 2, wherein the amplifier comprises a transimpedance amplifier configured to convert a current signal of the photodetector to a voltage signal as the electrical signal.

Example 4: The chip interconnect of example 2 or 3, wherein the amplifier comprises an equalizer configured to precondition the electrical signal before amplifying the electrical signal.

Example 5: The chip interconnect of any one or more of examples 2 to 4, further comprising a controller to regulate the amplifier.

Example 6: The chip interconnect of any one or more of the above examples, wherein the converter comprises a serializer coupled to the amplifier configured to convert the electrical signal to a differential data signal.

Example 7: The chip interconnect of any one or more of the above examples, wherein the converter drives the differential data signal to the output pins.

Example 8 The chip interconnect of any one or more of the above examples, wherein the output pins are coupled to circuit board traces coupled to pins of an external processing chip.

Example 9: The chip interconnect of any one or more of the above examples, wherein the output pins are configured to be coupled to a two-pin input port for a differential data signal of an external processing chip.

Example 10: The chip interconnect of any one or more of the above examples, wherein the chip interconnect is formed on a single substrate that is separate from an external processing chip.

Example 11: The chip interconnect of any one or more of the above examples, further comprising a substate and wherein the photodetector and the converter are formed on the substrate.

Example 12: A chip interconnect comprising: a two-wire coupling port having two input pins configured to couple a differential data signal from a source chip to the chip interconnect; a laser coupled to an amplifier configured to convert the differential data signal to an optical signal; and an optical fiber coupling port configured to couple the optical signal to an external optical fiber coupled to the chip interconnect.

Example 13: The chip interconnect of example 12, wherein the two input pins are coupled to circuit board traces coupled to pins of an external data source.

Example 14: The chip interconnect of examples 12 or 13, further comprising an amplifier coupled to the laser configured to convert the differential data signal to a pulse for the laser.

Example 15: The chip interconnect of any one or more of examples 12 to 14, further comprising an amplifier coupled to the two-wire coupling port configured to amplify the differential data signal.

Example 16: The chip interconnect of any one or more of examples 12 to 15, further comprising a controller to regulate the amplifier.

Example 17: A computing system comprising: a processing chip configured to receive a differential data signal at a two-pin input port; and a chip interconnect comprising a two-wire coupling port configured to couple the differential data signal to the two-pin input port of the processing chip, the chip interconnect further comprising: an optical fiber coupling port coupled to an optical fiber and configured to receive an optical signal from a data source through the optical fiber; a photodetector coupled to the optical fiber coupling port and configured to generate an electrical signal based on the optical signal at the optical fiber coupling port; and a converter coupled to receive the electrical signal and configured to generate the differential data signal based on the electrical signal and coupled to the two-wire coupling port to provide the differential data signal to the two-wire coupling port.

Example 18: The computing system of example 17, further comprising a substrate to carry the chip interconnect independent of the processing chip.

Example 19: A method comprising: receiving an optical signal at an optical fiber coupling port; generating an electrical signal in response to the optical signal received at the optical fiber coupling port at a photodetector; receiving the electrical signal and generating a differential data signal based on the electrical signal at a converter, and coupling the differential data signal to a two-wire coupling port.

Example 20: The method of example 19, wherein the generating the differential data signal comprises converting the electrical signal from a current signal of the photodetector to a voltage signal and serializing the voltage signal to the differential data signal.

What is claimed is:

1. A chip interconnect comprising:
an optical fiber coupling port;
a photodetector coupled to the optical fiber coupling port configured to generate an electrical signal in response to an optical signal received at the optical fiber coupling port;
a converter coupled to receive the electrical signal and configured to generate a differential data signal based on the electrical signal; and
a two-wire coupling port comprising output pins of the chip interconnect, the two-wire coupling port configured to couple the differential data signal to the output pins.

2. The chip interconnect of claim 1, further comprising an amplifier coupled to the photodetector configured to amplify the electrical signal and provide the electrical signal to the converter.

3. The chip interconnect of claim 2, wherein the amplifier comprises a transimpedance amplifier configured to convert a current signal of the photodetector to a voltage signal as the electrical signal.

4. The chip interconnect of claim 2, wherein the amplifier comprises an equalizer configured to precondition the electrical signal before amplifying the electrical signal.

5. The chip interconnect of claim 2, further comprising a controller to regulate the amplifier.

6. The chip interconnect of claim 1, wherein the converter comprises a serializer coupled to the amplifier configured to convert the electrical signal to a differential data signal.

7. The chip interconnect of claim 1, wherein the converter drives the differential data signal to the output pins.

8. The chip interconnect of claim 1, wherein the output pins are coupled to circuit board traces coupled to pins of an external processing chip.

9. The chip interconnect of claim 1, wherein the output pins are configured to be coupled to a two-pin input port for a differential data signal of an external processing chip.

10. The chip interconnect of claim 1, wherein the chip interconnect is formed on a single substrate that is separate from an external processing chip.

11. The chip interconnect of claim 1, further comprising a substrate and wherein the photodetector and the converter are formed on the substrate.

12. A chip interconnect comprising:
a two-wire coupling port having two input pins configured to couple a differential data signal from a source chip to the chip interconnect;
a laser coupled to an amplifier configured to convert the differential data signal to an optical signal; and
an optical fiber coupling port configured to couple the optical signal to an external optical fiber coupled to the chip interconnect.

13. The chip interconnect of claim 12, wherein the two input pins are coupled to circuit board traces coupled to pins of an external data source.

14. The chip interconnect of claim 12, further comprising an amplifier coupled to the laser configured to convert the differential data signal to a pulse for the laser.

15. The chip interconnect of claim 12, further comprising an amplifier coupled to the two-wire coupling port configured to amplify the differential data signal.

16. The chip interconnect of claim 12, further comprising a controller to regulate the amplifier.

17. A computing system comprising:
a processing chip configured to receive a differential data signal at a two-pin input port; and
a chip interconnect comprising a two-wire coupling port configured to couple the differential data signal to the two-pin input port of the processing chip, the chip interconnect further comprising:
an optical fiber coupling port coupled to an optical fiber and configured to receive an optical signal from a data source through the optical fiber;
a photodetector coupled to the optical fiber coupling port and configured to generate an electrical signal based on the optical signal at the optical fiber coupling port; and
a converter coupled to receive the electrical signal and configured to generate the differential data signal based on the electrical signal and coupled to the two-wire coupling port to provide the differential data signal to the two-wire coupling port.

18. The computing system of claim 17, further comprising a substrate to carry the chip interconnect independent of the processing chip.

19. A method comprising:
receiving an optical signal at an optical fiber coupling port;
generating an electrical signal in response to the optical signal received at the optical fiber coupling port at a photodetector;
receiving the electrical signal and generating a differential data signal based on the electrical signal at a converter; and
coupling the differential data signal to a two-wire coupling port.

20. The method of claim 19, wherein the generating the differential data signal comprises converting the electrical signal from a current signal of the photodetector to a voltage signal and serializing the voltage signal to the differential data signal.
